(19) United States
(12) Patent Application Publication
(10) Pub. No.: US 2019/0018778 A1
(43) Pub. Date: Jan. 17, 2019

(54) HIERARCHICAL NAND MEMORY DEVICE CAPABLE OF PERFORMING CONCURRENT AND PIPELINE OPERATIONS

(71) Applicant: Peter Wung LEE, Saratoga, CA (US)

(72) Inventor: Peter Wung LEE, Saratoga, CA (US)

(21) Appl. No.: 16/119,754

(22) Filed: Aug. 31, 2018

Related U.S. Application Data
(63) Continuation-in-part of application No. 15/615,883, filed on Jun. 7, 2017.
(60) Provisional application No. 62/347,079, filed on Jun. 7, 2016.

(51) Int. Cl. G06F 12/0855; G06F 12/0893; G11C 16/10; G11C 16/24; H01L 27/11551; H01L 27/11578

(52) U.S. Cl. CPC G06F 12/0855; G06F 12/0893; H01L 27/11578; G11C 16/24; H01L 27/11551; G11C 16/10

(57) ABSTRACT

A hierarchical NAND memory device includes: memory units each including memory groups; dynamic cache register (DCR) units each including DCR groups; switching circuit units each including switching circuits that are respectively coupled to the memory groups of a respective memory unit and that are respectively coupled to the DCR groups of a respective DCR unit; data register units each including data registers that are respectively coupled to the switching circuits of a respective switching circuit units; a data line (DL) unit each including DLs; and DL switch units each including switches that are respectively coupled between the data registers of a respective data register unit and the DLs of the DL unit.

### CROSS-REFERENCE TO RELATED APPLICATION

This application is a Continuation-in-Part Application of U.S. patent application Ser. No. 15/615,883, filed on Jun. 7, 2017 and claiming benefit of U.S. Provisional Patent Application No. 62/347,079.

### FIELD

The disclosure relates to a NAND memory device, and more particularly to a hierarchical NAND memory device capable of performing concurrent and pipeline operations.

### BACKGROUND

NAND memory devices are widely used today in various low-cost, non-volatile storage applications. Despite its popularity, a conventional NAND memory device has been notoriously known for its inherent performance bottlenecks such as long latency, poor data reliability, high power consumption, etc.

### SUMMARY

Therefore, an object of the disclosure is to provide a hierarchical NAND memory device that is capable of performing concurrent and pipeline operations, and that can alleviate at least one of the drawbacks of the prior art.

According to the disclosure, the hierarchical NAND memory device includes a number (M) of memory units, a number (M) of dynamic cache register (DCR) units, a number (M) of switching circuit units, a number (M) of data register units, a data line (DL) unit and a number (M) of DL switch units, where M is an integer greater than or equal to two. The memory units are arranged in a first direction. Each of the memory units includes a number (N) of memory groups which are arranged in a second direction orthogonal to the first direction, and each of which includes a plurality of three-dimensional (3D) NAND strings, where N is an integer greater than or equal to two. The DCR units are arranged in the first direction. Each of the DCR units includes a number (N) of DCR groups which are arranged in the second direction, and each of which includes a plurality of 3D capacitor strings. Each of the switching circuit units includes a number (N) of switching circuits. For each of the switching circuit units, a respective one of the memory units and a respective one of the DCR units, each of the switching circuits is coupled to the 3D NAND strings of a respective one of the memory groups and the 3D capacitor strings of a respective one of the DCR groups. Each of the data register units includes a number (N) of data registers. For each of the data register units and a respective one of the switching circuit units, each of the data registers is coupled to a respective one of the switching circuits. The DL unit includes a number (N) of DLs. Each of the DL switch units includes a number (N) of DL switches. For each of the DL switch units, a respective one of the data register units and the DL unit, each of the DL switches is coupled between a respective one of the data registers and a respective one of the DLs.

### BRIEF DESCRIPTION OF THE DRAWINGS

Other features and advantages of the disclosure will become apparent in the following detailed description of the embodiments with reference to the accompanying drawings, of which:

FIGS. 1 and 2 are circuit block diagrams illustrating a first embodiment of a hierarchical NAND memory device according to the disclosure;

FIG. 3 is a block diagram illustrating a data register of the first embodiment;

FIG. 4 is a structural diagram illustrating an exemplary implementation of the first embodiment;

FIG. 5 is a structural diagram illustrating another exemplary implementation of the first embodiment;

FIG. 6 is a structural diagram illustrating yet another exemplary implementation of the first embodiment;

FIGS. 7 and 8 are circuit block diagrams illustrating a second embodiment of the hierarchical NAND memory device according to the disclosure;

FIGS. 9 and 10 are circuit block diagrams illustrating a third embodiment of the hierarchical NAND memory device according to the disclosure; and

FIG. 11 is a circuit block diagram illustrating a fourth embodiment of the hierarchical NAND memory device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

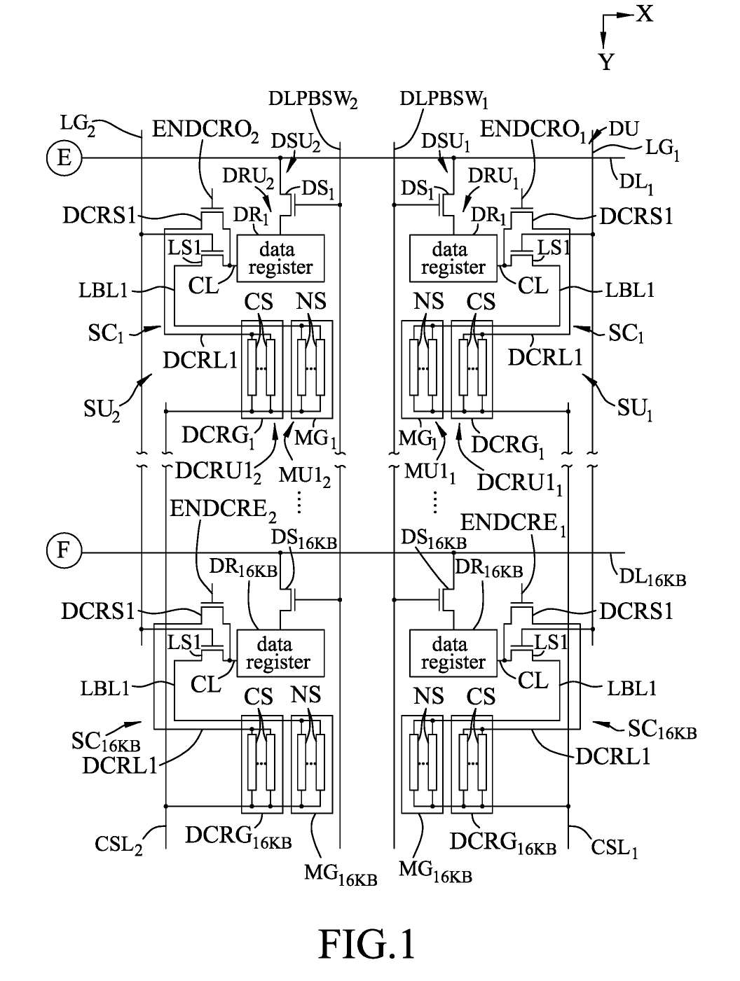

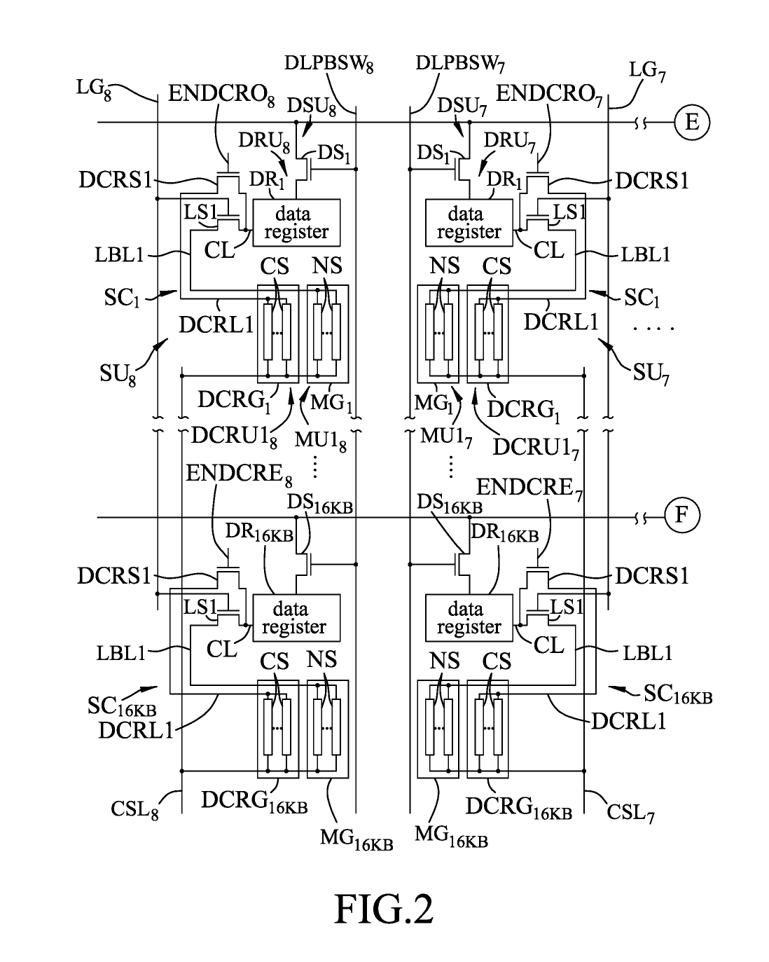

Referring to FIGS. 1 and 2, a first embodiment of a hierarchical NAND memory device according the disclosure includes a number (M) of first memory units (MU1₁-MU1_{M}), a number (M) of first dynamic cache register (DCR) units (DCRU1₁-DCRU1_{M}), a number (M) of switching circuit units (SU₁-SU_{M}), a number (M) of data register units (DRU₁-DRU_{M}), a data line (DL) unit (DU), a number (M) of DL switch units (DSU₁-DSU_{M}), a number (M) of LBL switch control lines (LG₁-LG_{M}), a number (M) of first DCR switch control lines (ENDCRO₁-ENDCRO_{M}), a number (M) of second DCR switch control lines (ENDCRE₁-ENDCRE_{M}), a number (M) of DL switch control lines (DLPBSW₁-DLPBSW_{M}) and a number (M) of common source lines (CSL₁-CSL_{M}), where M is an integer greater than or equal to two. For illustration purposes, M=8 in this embodiment.

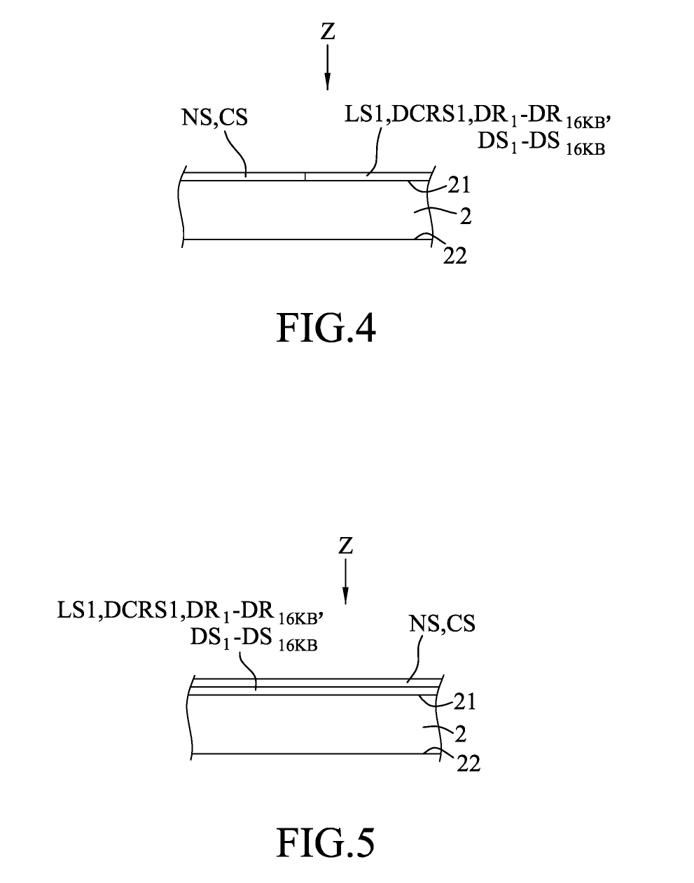

The first memory units (MU1₁-MU1₈) are arranged in a first direction (X). Each of the first memory units (MU1₁-MU1₈) includes a number (N) of memory groups (MG₁-MG_{N}) which are arranged in a second direction (Y) orthogonal to the first direction (X), and each of which includes a plurality of three-dimensional (3D) NAND strings (NS), where N is an integer greater than or equal to two. For illustration purposes, N=16 KB (i.e., 16×1024×8) in this embodiment. Each of the 3D NAND strings (NS) includes a plurality of 3D NAND cells (not shown) that are stacked in a third direction (Z) (see FIG. 4) orthogonal to the first and second directions (X, Y). Each of the 3D NAND cells can store at least one bit of data, may be a 2-poly floating-gate 3D NAND cell or a 1-poly charge-trapping 3D NAND cell, and may be erased by Fowler-Nordheim tunneling mechanism or gate-induced drain leakage mechanism.

The first DCR units (DCRU1₁-DCRU1₈) are arranged in the first direction (X). Each of the first DCR units (DCRU1₁-DCRU1₈) includes a number (N) (i.e., 16 KB in this embodiment) of DCR groups (DCRG₁-DCRG_{16KB}) which are arranged in the second direction (Y), and each of which includes a plurality of 3D capacitor strings (CS). Each of the 3D capacitor strings (CS) extends in the third direction (Z) (see FIG. 4).

Each of the switching circuit units (SU₁-SU₈) includes a number (N) (i.e., 16 KB in this embodiment) of switching circuits (SC₁-SC_{16KB}). In this embodiment, each of the switching circuits (SC₁-SC_{16KB}) includes a first local bit line (LBL) (LBL1), a first DCR line (DCRL1), a connecting line (CL), a first LBL switch (LS1) that is coupled between the first LBL (LBL1) and the connecting line (CL) of the switching circuit, and a first DCR switch (DCRS1) that is coupled between the first DCR line (DCRL1) and the connecting line (CL) of the switching circuit. For each of the switching circuit units (SU₁-SU₈) and a respective one of the first memory units (MU1₁-MU1₈), the first LBL (LBL1) of each of the switching circuits (SC₁-SC_{16KB}) is coupled to the 3D NAND strings (NS) of a respective one of the memory groups (MG₁-MG_{16KB}). For each of the switching circuit units (SU₁-SU₈) and a respective one of the first DCR units (DCRU1₁-DCRU1₈), the first DCR line (DCRL1) of each of the switching circuits (SC₁-SC_{16KB}) coupled to the 3D capacitor strings (CS) of a respective one of the DCR groups (DCRG₁-DCRG_{16KB}).

Each of the data register units (DRU₁-DRU₈) includes a number (N) (i.e., 16 KB in this embodiment) of data registers (DR₁-DR_{16KB}). For each of the data register units (DRU₁-DRU₈) and a respective one of the switching circuit units (SU₁-SU₈), each of the data registers (DR₁-DR_{16KB}) is coupled to the connecting line (CL) of a respective one of the switching circuits (SC₁-SC_{16KB}).

The DL unit (DU) includes a number (N) (i.e., 16 KB in this embodiment) of DLs (DL₁-DL_{16KB}).

Each of the DL switch units (DSU₁-DSU₈) includes a number (N) (i.e., 16 KB in this embodiment) of DL switches (DS₁-DS_{16KB}). For each of the DL switch units (DSU₁-DSU₈), a respective one of the data register units (DRU₁-DRU₈) and the DL unit (DU), each of the DL switches (DS₁-DS_{16KB}) is coupled between a respective one of the data registers (DR₁-DR_{16KB}) and a respective one of the DLs (DL₁-DL_{16KB}).

Each of the LBL switch control lines (LG₁-LG₈) is coupled to the first LBL switches (LS1) of the switching circuits (SC₁-SC_{16KB}) of a respective one of the switching circuit units (SU₁-SU₈), and is used to transmit a respective control signal for controlling operation of the first LBL switches (LS1) coupled thereto between conduction and non-conduction.

Each of the first DCR switch control lines (ENDCRO₁-ENDCRO₈) is coupled to the first DCR switches (DCRS1) of a first half of the switching circuits (SC₁, SC₃, . . . , SC_{16KB-1}) of a respective one of the switching circuit units (SU₁-SU₈), and is used to transmit a respective control signal for controlling operation of the first DCR switches (DCRS1) coupled thereto between conduction and non-conduction.

Each of the second DCR switch control lines (ENDCRE₁-ENDCRE₈) is coupled to the first DCR switches (DCRS1) of a second half of the switching circuits (SC₂, SC₄, . . . , SC_{16KB}) of a respective one of the switching circuit units (SU₁-SU₈), and is used to transmit a respective control signal for controlling operation of the first DCR switches (DCRS1) coupled thereto between conduction and non-conduction.

In this embodiment, for each of the first DCR units (DCRU1₁-DCRU1₈) and the respective one of the switching circuit units (SU₁-SU₈), some of the DCR groups (DCRG₁, DCRG₃, . . . , DCRG_{16KB-1}) that respectively correspond to the first DCR switches (DCRS1) of the first half of the switching circuits (SC₁, SC₃, . . . , SC_{16KB-1}) are interleaved in the second direction (Y) with some of the DCR groups (DCRG₂, DCRG₄, . . . , DCRG_{16KB}) that respectively correspond to the first DCR switches (DCRS1) of the second half of the switching circuits (SC₂, SC₄, . . . , SC_{16KB}).

Each of the DL switch control lines (DLPBSW₁-DLPBSW₈) is coupled to the DL switches (DS₁-DS_{16KB}) of a respective one of the DL switch units (DSU₁-DSU₈), and is used to transmit a respective control signal for controlling operation of the DL switches (DS₁-DS_{16KB}) coupled thereto between conduction and non-conduction.

Each of the common source lines (CSL₁-CSL₈) is coupled to the 3D NAND strings (NS) of the memory groups (MG₁-MG_{16KB}) of a respective one of the first memory units (MU1₁-MU1₈) and the 3D capacitor strings (CS) of the DCR groups (DCRG₁-DCRG_{16KB}) of a respective one of the first DCR units (DCRU1₁-DCRU1₈).

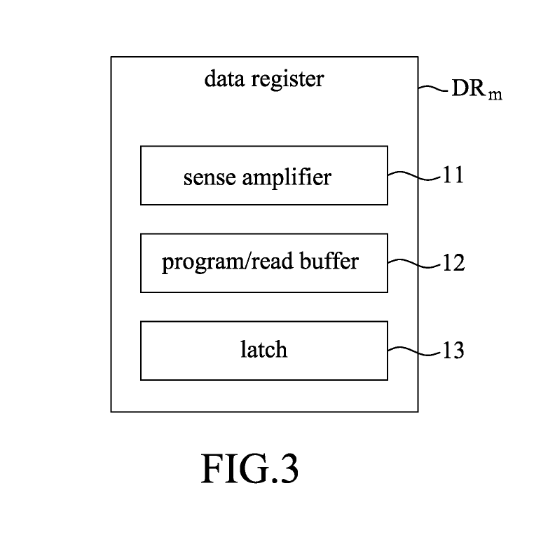

The data registers (DR₁-DR_{16KB}) assist in operations of the hierarchical NAND memory device of this embodiment (e.g., program, read, erase, etc.). Referring to FIG. 3, in this embodiment, each of the data registers (DR₁-DR_{16KB}) includes a sense amplifier 11, a program/read buffer 12 and a latch 13. The sense amplifier 11 may be a sense amplifier as disclosed in FIG. 5B of U.S. Pat. No. 9,230,677, FIG. 3 of U.S. Pat. No. 9,613,704 or FIG. 15 of U.S. Pat. No. 9,666,286, and details thereof are omitted herein for the sake of brevity. The program/read buffer 12 may be a combination of a program buffer and a matching logic as disclosed in FIG. 5B of U.S. Pat. No. 9,230,677, a combination of a program/read buffer and a page program check circuit as disclosed in FIG. 3 of U.S. Pat. No. 9,613,704, or a combination of a program/readbuffer and a page program verify circuit as disclosed in FIG. 15 of U.S. Pat. No. 9,666,286, and details thereof are omitted herein for the sake of brevity. The latch 13 may be a data buffer as disclosed in FIG. 5B of U.S. Pat. No. 9,230,677, a cache register as disclosed in FIG. 3 of U.S. Pat. No. 9,613,704, or a static cache register as disclosed in FIG. 15 of U.S. Pat. No. 9,666,286, and details thereof are omitted herein for the sake of brevity.

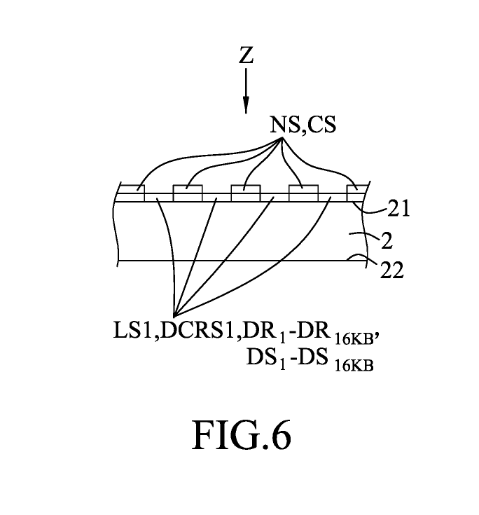

It should be noted that, as shown in FIG. 4, the 3D NAND strings (NS) of the first memory units (MU1₁-MU1₈), the 3D capacitor strings (CS) of the first DCR units (DRU1₁-DRU1₈, the switches (LS1, DCRS1) of the switching circuit units (SU₁-SU₈), the data registers (DR₁-DR_{16KB}) of the data register units (DRU₁-DRU₈) and the DL switches (DS₁-DS_{16KB}) of the DL switch units (DSU₁-DSU₈) may be formed on the same surface (e.g., a first surface 21) of a substrate 2, with the 3D NAND strings (NS) of the first memory units (MU1₁-MU1₈) and the 3D capacitor strings (CS) of the first DCR units (DRU1₁-DRU1₈) arranged to one side of the same surface, and the switches (LS1, DCRS1) of the switching circuit units (SU₁-SU₈), the data registers (DR₁-DR_{16KB}) of the data register units (DRU₁-DRU₈) and the DL switches (DS₁-DS_{16KB}) of the DL switch units (DSU₁-DSU₈) arranged to an opposite side of the same surface. Alternatively, as shown in FIGS. 5 and 6, the 3D NAND strings (NS) of the first memory units (MU1₁-MU1₈), the 3D capacitor strings (CS) of the first DCR units (DRU1₁-DRU1₈), the switches (LS1, DCRS1) of the switching circuit units (SU₁-SU₈), the data registers (DR₁-DR_{16KB}) of the data register units (DRU₁-DRU₈) and the DL switches (DS₁-DS_{16KB}) of the DL switch units (DSU₁-DSU₈) may be formed on the same surface (e.g., the first surface 21), with the 3D NAND strings (NS) of the first memory units (MU1₁-MU1₈) and the 3D capacitor strings (CS) of the first DCR units (DRU1₁-DRU1₈) in a layer and the switches (LS1, DCRS1) of the switching circuit units (SU₁-SU₈), the data registers (DR₁-DR_{16KB}) of the data register units (DRU₁-DRU₈) and the DL switches (DS₁-DS_{16KB}) of the DL switch units (DSU₁-DSU₈) in another layer. As shown in FIG. 5, the layers may overlap with each other, thereby reducing a size of the hierarchical NAND memory device of this embodiment; or, as shown in FIG. 6, the layers may tangentially be in contact with each other, such that they may not overlap with each other as a result. In addition, each of the switches (LS1, DCRS1, DS₁-DS_{16KB}) may be a transistor with a two-dimensional (2D) or 3D structure.

Referring back to FIGS. 1 and 2, for each of the first memory units (MU1₁-MU1₈), since the first LBL switches (LS1) of the switching circuits (SC₁-SC_{16KB}) of the corresponding one of the switching circuit units (SU₁-SU₈) are controlled by the same control signal, and since the DL switches (DS₁-DS_{16KB}) of the corresponding one of the DL switch units (DSU₁-DSU₈) are controlled by the same control signal, all bit line operations (e.g., all bit line program, all bit line read, etc.) can be achieved. In addition, for each of the first DCR units (DCRU1₁-DCRU1₈), since the first DCR switches (DCRS1) of the first and second halves of the switching circuits (SC₁-SC_{16KB}) of the corresponding one of the switching circuit units (SU₁-SU₈) are controlled by different control signals, half bit line operations (e.g., half bit line recall, etc.) can be achieved.

The hierarchical NAND memory device of this embodiment is capable of performing concurrent and pipeline operations (e.g., program, read, erase, etc.). In an example of the concurrent operations, a number (J) of pages of data (with each page including a number (N) (i.e., 16 KB in this embodiment) of bits) are transferred sequentially from the DL unit (DU) and respectively to a number (J) of the first DCR units (DCRU1₁-DCRU1₈) page by page, and then are concurrently and respectively programmed into a number (J) of the first memory units (MU1₁-MU1₈), where J is an integer and 2≤J≤M (i.e., 2≤J≤8 in this embodiment). In another example of the concurrent operations, a number (J) of pages of data (with each page including a number (N) (i.e., 16 KB in this embodiment) of bits) respectively stored in a number (J) of the first memory units (MU1₁-MU1₈) are concurrently and respectively read to (the first LBLs (LBL1) of) a number (J) of the switching circuit units (SU₁-SU₈), and then are sequentially transferred to the DL unit (DU) page by page. The pipeline operations of the hierarchical NAND memory device of this embodiment are similar to those of the conventional NAND memory device, and details thereof are omitted herein for the sake of brevity.

In view of the above, the hierarchical NAND memory device of this embodiment has the following advantages:

1. Since the first LBL (LBL1) of each of the switching circuits (SC₁-SC_{16KB}) of the switching circuit units (SU₁-SU₈) is coupled to the 3D NAND strings (NS) of a respective one of the memory groups (MG₁-MG_{16KB}) of the first memory units (MU1₁-MU1₈), each of the first LBLs (LBL1) can have a relatively small capacitance, resulting in relatively short latency and relatively low power consumption of the hierarchical NAND memory device.

2. Since the hierarchical NAND memory device can perform concurrent operations, each of the 3D NAND strings (NS) of the memory groups (MG₁-MG_{16K}) of the first memory units (MU1₁-MU1₈) would not have to frequently withstand high-voltage (e.g. 20V) or medium-high-voltage (e.g., 6V or 10V) stresses, resulting in relatively good data reliability of the hierarchical NAND memory device.

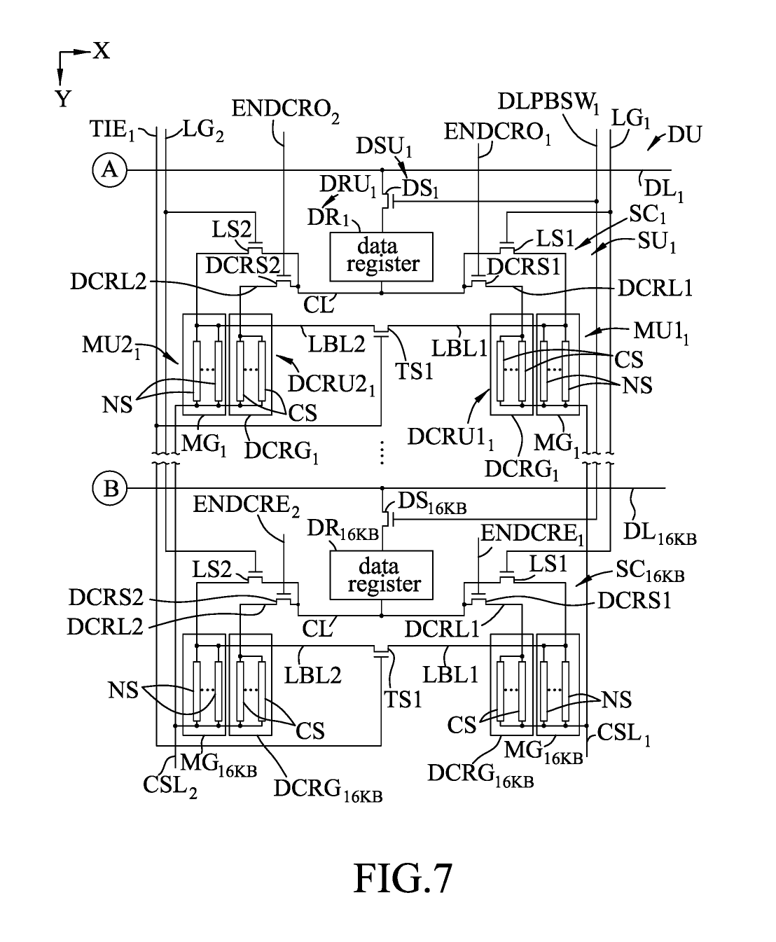

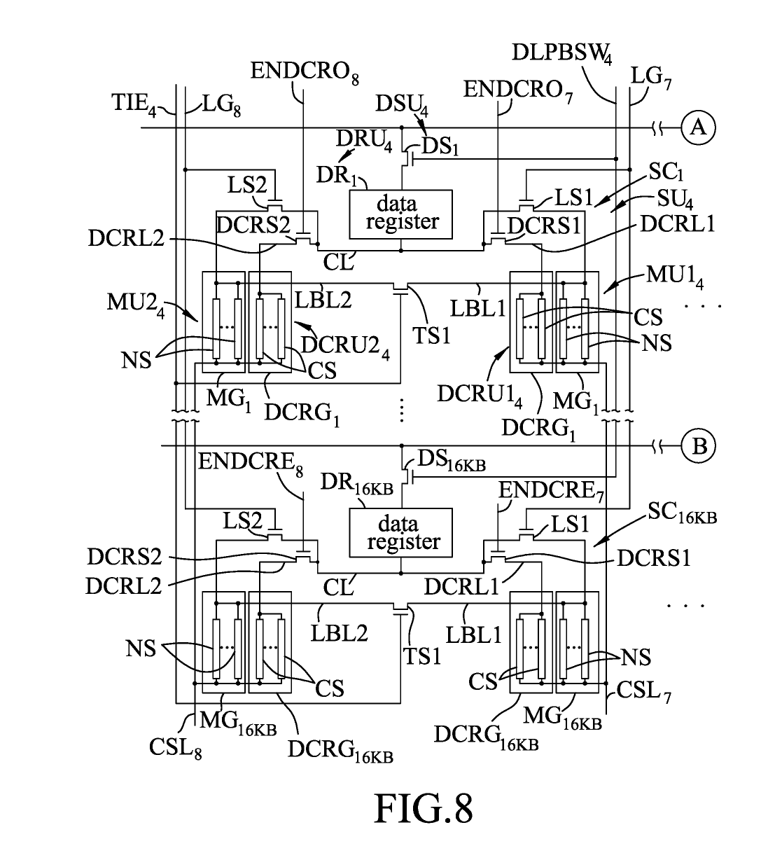

Referring to FIGS. 7 and 8, a second embodiment of the hierarchical NAND memory device according to the disclosure is a modification of the first embodiment, and differs from the first embodiment in that: (a) M=4; (b) the hierarchical NAND memory device further includes a number (M) (i.e., four in this embodiment) of second memory units (MU2₁-MU2₄), a number (M) of second DCR units (DCRU2₁-DCRU2₄) and a number (M) of tie switch control lines (TIE₁-TIE₄); (c) each of the switching circuits (SC₁-SC_{16KB}) further includes a second LBL (LBL2), a second DCR line (DCRL2), a second LBL switch (LS2), a second DCR switch (DCRS2) and a first tie switch (TS1); and (d) the hierarchical NAND memory device includes a number (2×M) (i.e., eight in this embodiment) of LBL switch control lines (LG₁-LG₈), a number (2×M) of first DCR switch control lines (ENDCRO₁-ENDCRO₈), a number (2×M) of second DCR switch control lines (ENDCRE₁-ENDCRE₈) and a number (2×M) of common source lines (CSL₁-CSL₈), instead of a number (M) of LBL switch control lines, a number (M) of first DCR switch control lines, a number (M) of second DCR switch control lines and a number (M) of common source lines.

In the second embodiment, the second memory units (MU2₁-MU2₄) are arranged in the first direction (X). Each of the second memory units (MU2₁-MU2₄) includes a number (N) (i.e., 16 KB in this embodiment) of memory groups (MG₁-MG_{16KB}) which are arranged in the second direction (Y), and each of which includes a plurality of 3D NAND strings (NS). Each of the 3D NAND strings (NS) of the second memory units (MU2₁-MU2₄) has a configuration identical to that of each of the 3D NAND strings (NS) of the first memory units (MU1₁-MU1₄).

The second DCR units (DCRU2₁-DCRU2₄) are arranged in the first direction (X). Each of the second DCR units (DCRU2₁-DCRU2₄) includes a number (N) (i.e., 16 KB in this embodiment) of DCR groups (DCRG₁-DCRG_{16KB}) which are arranged in the second direction (Y), and each of which includes a plurality of 3D capacitor strings (CS). Each of the 3D capacitor strings (CS) of the second DCR units (DCRU2₁-DCRU2₄) has a configuration identical to that of each of the 3D capacitor strings (CS) of the first DCR units (DCRU1₁-DCRU1₄).

For each of the switching circuits (SC₁-SC_{16KB}), the second LBL switch (LS2) is coupled between the second LBL (LBL2) and the connecting line (CL); the second DCR switch (DCRS2) is coupled between the second DCR line (DCRL2) and the connecting line (CL); and the first tie switch (TS1) is coupled between the first and second LBLs (LBL1, LBL2), and allows charge sharing between the same when conducting. For each of the switching circuit units (SU₁-SU₄) and a respective one of the second memory units (MU2₁-MU2₄), the second LBL (LBL2) of each of the switching circuits (SC₁-SC_{16KB}) is coupled to the 3D NAND strings (NS) of a respective one of the memory groups (MG₁-MG_{16KB}. For each of the switching circuit units (SU₁-SU₄) and a respective one of the second DCR units (DCRU2₁-DCRU2₄), the second DCR line (DCRL2) of each of the switching circuits (SC₁-SC_{16KB}) is coupled to the 3D capacitor strings (CS) of a respective one of the DCR groups (DCRG₁-DCRG_{16KB}).

Each of the tie switch control lines (TIE₁-TIE₄) is coupled to the first tie switches (TS1) of the switching circuits (SC₁-SC_{16KB}) of a respective one of the switching circuit units (SU₁-SU₄), and is used to transmit a respective control signal for controlling operation of the first tie switches (TS1) coupled thereto between conduction and non-conduction.

Each of a first half of the LBL switch control lines LG₁, LG₃, LG₅, LG₇) is coupled to the first LBL switches (LS1) of the switching circuits (SC₁-SC_{16KB}) of a respective one of the switching circuit units (SU₁-SU₄), and is used to transmit a respective control signal for controlling operation of the first LBL switches (LS1) coupled thereto between conduction and non-conduction. Likewise, each of a second half of the LBL switch control lines (LG₂, LG₄, LG₆, LG₈) is coupled to the second LBL switches (LS2) of the switching circuits (SC₁-SC_{16KB}) of a respective one of the switching circuit units (SU₁-SU₄), and is used to transmit a respective control signal for controlling operation of the second LBL switches (LS2) coupled thereto between conduction and non-conduction.

Each of a first half of the first DCR switch control lines (ENDCRO₁, ENDCRO₃, ENDCRO₅, ENDCRO₇) is coupled to the first DCR switches (DCRS1) of a first half of the switching circuits (SC₁, SC₃, . . . , SC_{16KB-1}) of a respective one of the switching circuit units (SU₁-SU₄), and is used to transmit a respective control signal for controlling operation of the first DCR switches (DCRS1) coupled thereto between conduction and non-conduction. Likewise, each of a second half of the first DCR switch control lines (ENDCRO2, ENDCRO₄, ENDCRO₆, ENDCRO₈) is coupled to the second DCR switches (DCRS2) of the first half of the switching circuits (SC₁, SC₃, . . . , SC_{16KB-1}) of a respective one of the switching circuit units (SU₁-SU₄), and is used to transmit a respective control signal for controlling operation of the second DCR switches (DCRS2) coupled thereto between conduction and non-conduction.

Each of a first half of the second DCR switch control lines (ENDCRE₁, ENDCRE₃, ENDCRE₅, ENDCRE₇) is coupled to the first DCR switches (DCRS1) of a second half of the switching circuits (SC₂, SC₄, . . . , SC_{16KB}) of a respective one of the switching circuit units (SU₁-SU₄), and is used to transmit a respective control signal for controlling operation of the first DCR switches (DCRS1) coupled thereto between conduction and non-conduction. Likewise, each of a second half of the second DCR switch control lines (ENDCRE₂, ENDCRE₄, ENDCRE₆, ENDCRE₈) is coupled to the second DCR switches (DCRS2) of the second half of the switching circuits (SC₂, SC₄, . . . , SC_{16KB}) of a respective one of the switching circuit units (SU₁-SU₄), and is used to transmit a respective control signal for controlling operation of the second DCR switches (DCRS2) coupled thereto between conduction and non-conduction.

In this embodiment, for each of the first DCR units (DCRU1₁-DCRU1₄) and the respective one of the switching circuit units (SU₁-SU₄), some of the DCR groups (DCRG₁, DCRG₃, . . . , DCRG_{16KB-1}) that respectively correspond to the first DCR switches (DCRS1) of the first half of the switching circuits (SC₁, SC₃, . . . , SC_{16KB-1}) are interleaved in the second direction (Y) with some of the DCR groups (DCRG₂, DCRG₄, . . . , DCRG_{16KB}) that respectively correspond to the first DCR switches (DCRS1) of the second half of the switching circuits (SC₂, SC₄, . . . , SC_{16KB}); and for each of the second DCR units (DCRU2₁-DCRU2₄) and the respective one of the switching circuit units (SU₁-SU₄), some of the DCR groups (DCRG₁, DCRG₃, . . . , DCRG_{16KB-1}) that respectively correspond to the second DCR switches (DCRS2) of the first half of the switching circuits (SC₁, SC₃, . . . , SC_{16KB-1}) are interleaved in the second direction (Y) with some of the DCR groups (DCRG₂, DCRG₄, . . . , DCRG_{16KB}) that respectively correspond to the second DCR switches (DCRS2) of the second half of the switching circuits (SC₂, SC₄, . . . , SC_{16KB}).

Each of the common source lines (CSL₁-CSL₈) is coupled to the 3D NAND strings (NS) of a respective one of the first and second memory units (MU1₁-MU1₄, MU2₁-MU2₄) and the 3D capacitor strings (CS) of a respective one of the first and second DCR units (DCRU1₁-DCRU1₄, DCRU2₁-DCRU2₄).

It should be noted that, in this embodiment, the 3D NAND strings (NS) of the second memory units (MU2₁-MU2₄) and the 3D capacitor strings (CS) of the second DCR units (DCRU2₁-DCRU2₄) are coplanar with the 3D NAND strings (NS) of the first memory units (MU1₁-MU1₄) and the 3D capacitor strings (CS) of the first DCR units (DCRU1₁-DCRU1₄); the switches (LS2, DCRS2, TS1) of the switching circuit units (SU₁-SU₄) are coplanar with the switches (LS1, DCRS1) of the switching circuit units (SU₁-SU₄), the data registers (DR₁-DR_{16KB}) of the data register units (DRU₁-DRU₄) and the DL switches (DS₁-DS_{16KB}) of the DL switch units (DSU₁-DSU₄); and each of the switches (LS2, DCRS2, TS1) may be a transistor with a 2D or 3D structure.

For each of the first and second memory units (MU1₁-MU1₄, MU2₁-MU2₄), since the corresponding LBL switches (LS1/LS2) of the switching circuits (SC₁-SC_{16KB}) of the corresponding one of the switching circuit units (SU₁-SU₄) are controlled by the same control signal, and since the DL switches (DS₁-DS_{16KB}) of the corresponding one of the DL switch units (DSU₁-DSU₄) are controlled by the same control signal, all bit line operations (e.g., all bit line program, all bit line read, etc.) can be achieved. In addition, for each of the first and second DCR units (DCRU1₁-DCRU1₄, DCRU2₁-DCRU2₄), since the corresponding DCR switches (DCRS1/DCRS2) of the first and second halves of the switching circuits (SC₁-SC_{16KB}) of the corresponding one of the switching circuit units (SU₁-SU₄) are controlled by different control signals, half bit line operations (e.g., half bit line recall, etc.) can be achieved.

The hierarchical NAND memory device of this embodiment is capable of performing concurrent and pipeline operations (e.g., program, read, erase, etc.). In an example of the concurrent operations, a number (J) of pages of data (with each page including a number (N) (i.e., 16 KB in this embodiment) of bits) are transferred sequentially from the DL unit (DU) and respectively to a number (J) of the first DCR units (DCRU1₁-DCRU1₄) page by page, and then are concurrently and respectively programmed into a number (J) of the first memory units (MU1₁-MU1₄), where J is an integer and 2≤J≤M (i.e., 2≤J≤4 in this embodiment). In another example of the concurrent operations, a number (J) of pages of data (with each page including a number (N) (i.e., 16 KB in this embodiment) of bits) respectively stored in a number (J) of the second memory units (MU2₁-MU2₄) are concurrently and respectively read to (the second LBLs (LBL2) of) a number (J) of the switching circuit units (SU₁-SU₄), and then are sequentially transferred to the DL unit (DU) page by page. The pipeline operations of the hierarchical NAND memory device of this embodiment are similar to those of the conventional NAND memory device, and details thereof are omitted herein for the sake of brevity.

It should be noted that, when a total number of the first and second memory units (MU1₁-MU1₄, MU2₁-MU2₄) of this embodiment is equal to the number of the first memory units (MU1₁-MU1₈) (see FIGS. 1 and 2) of the first embodiment, a number of the data register units (DRU₁-DRU₄) required in this embodiment is half a number of the data register units (DRU₁-DRU₈) (see FIGS. 1 and 2) required in the first embodiment, which is beneficial to reduce the size of the hierarchical NAND memory device of this embodiment.

In view of the above, the hierarchical NAND memory device of this embodiment has the following advantages:

1. Since the first LBL (LBL1) of each of the switching circuits (SC₁-SC_{16KB}) of the switching circuit units (SU₁-SU₄) is coupled to the 3D NAND strings (NS) of a respective one of the memory groups (MG₁-MG_{16KB}) of the first memory units (MU1₁-MU1₄), and since the second LBL (LBL2) of each of the switching circuits (SC₁-SC_{16KB}) of the switching circuit units (SU₁-SU₄) is coupled to the 3D NAND strings (NS) of a respective one of the memory groups (MG₁-MG_{16KB}) of the second memory units (MU2₁-MU2₄), each of the first and second LBLs (LBL1, LBL2) can have a relatively small capacitance, resulting in relatively short latency and relatively low power consumption of the hierarchical NAND memory device.

2. Since the hierarchical NAND memory device can perform concurrent operations, each of the 3D NAND strings (NS) of the memory groups (MG₁-MG_{16KB}) of the first and second memory units (MU1₁-MU1₄, MU2₁-MU2₄) would not have to frequently withstand high-voltage (e.g. 20V) or medium-high-voltage (e.g., 6V or 10V) stresses, resulting in relatively good data reliability of the hierarchical NAND memory device.

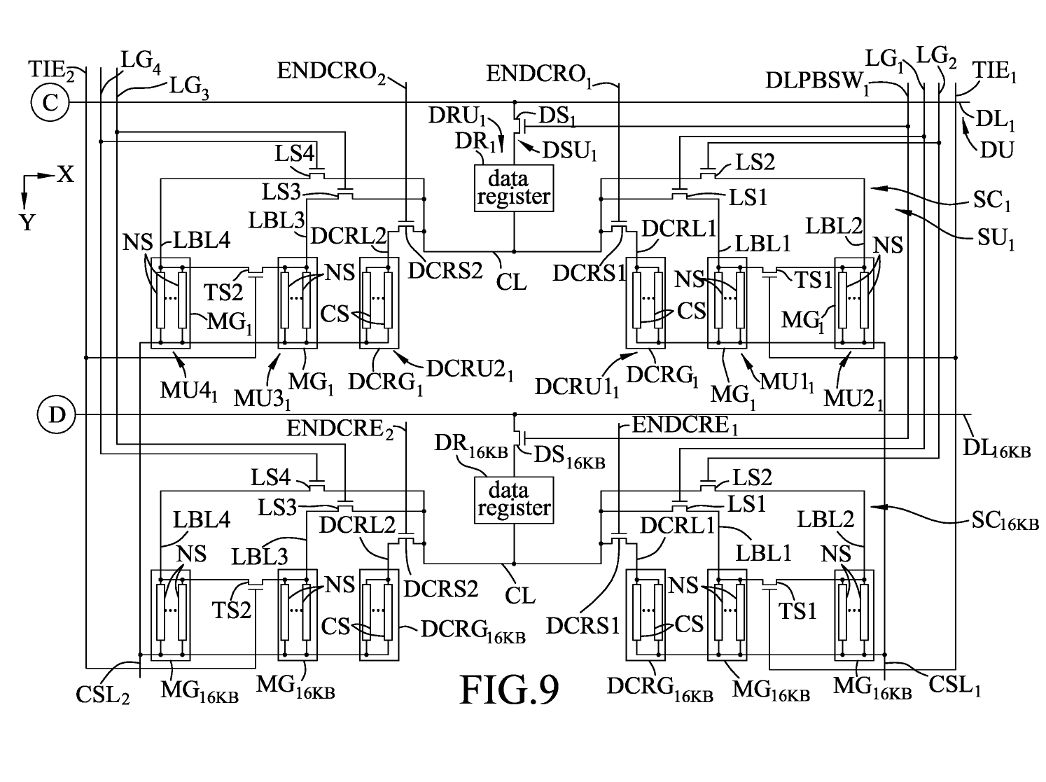

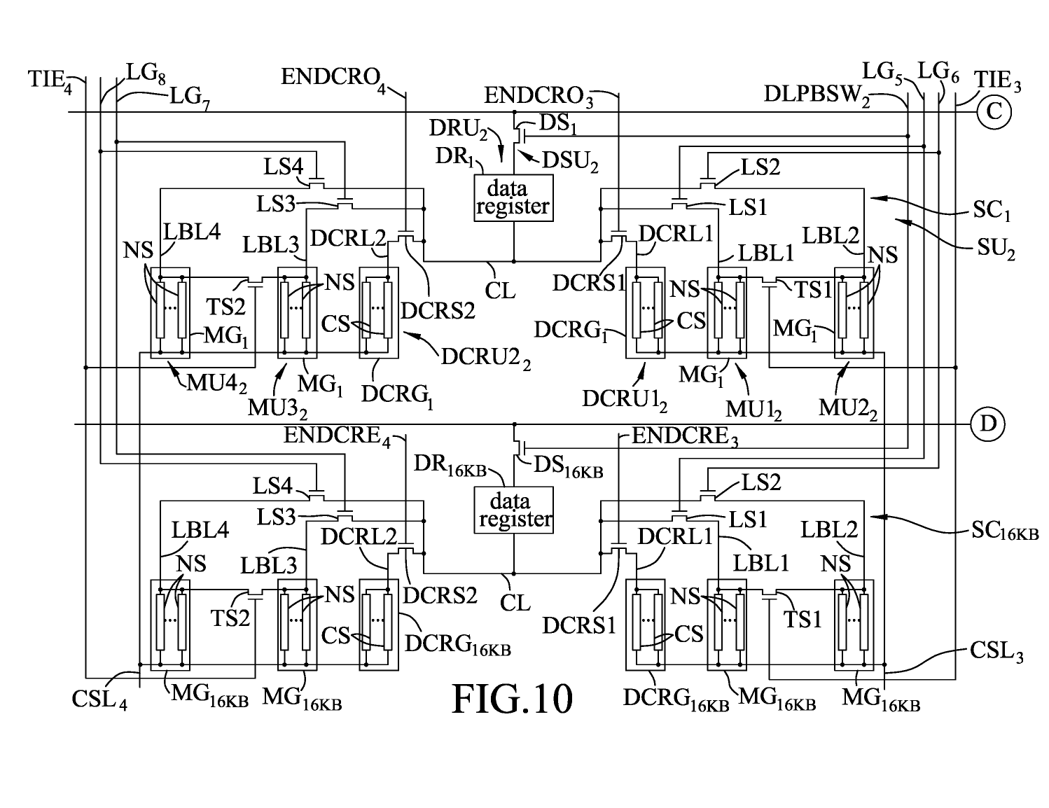

Referring to FIGS. 9 and 10, a third embodiment of the hierarchical NAND memory device according to the disclosure is a modification of the second embodiment, and differs from the second embodiment in that: (a) M=2; (b) the hierarchical NAND memory device further includes a number (M) (i.e., two in this embodiment) of third memory units (MU3₁, MU3₂) and a number (M) of fourth memory units (MU4₁, MU4₂); (c) each of the switching circuits (SC₁-SC-_{16KB}) further includes a third LBL (LBL3), a fourth LBL (LBL4), a third LBL switch (LS3), a fourth LBL switch (LS4) and a second tie switch (TS2); and (d) the hierarchical NAND memory device includes a number (4×M) (i.e., eight in this embodiment) of LBL switch control lines (LG₁-LG₈) and a number (2×M) (i.e., four in this embodiment) of tie switch control lines (TIE₁-TIE₄), instead of a number (2×M) of LBL switch control lines and a number (M) of tie switch control lines. In addition, the third embodiment further differs from the second embodiment in the connection of each common source line (CSL₁-CSL₄).

In the third embodiment, the third and fourth memory units (MU3₁, MU3₂, MU4₁, MU4₂) are arranged in the first direction (X). Each of the third and fourth memory units (MU3₁, MU3₂, MU4₁, MU4₂) includes a number (N) (i.e., 16 KB in this embodiment) of memory groups (MG₁-MG_{16KB}) which are arranged in the second direction (Y), and each of which includes a plurality of 3D NAND strings (NS). Each of the 3D NAND strings (NS) of the third and fourth memory units (MU3₁, MU3₂, MU4₁, MU4₂) has a configuration identical to that of each of the 3D NAND strings (NS) of the first and second memory units (MU1₁, MU1₂, MU2₁, MU2₂).

For each of the switching circuits (SC₁-SC_{16KB}), the third LBL switch (LS3) is coupled between the third LBL (LBL3) and the connecting line (CL); the fourth LBL switch (LS4) is coupled between the fourth LBL (LBL4) and the connecting line (CL); and the second tie switch (TS2) is coupled between the third and fourth LBLs (LBL3, LBL4), and allows charge sharing between the same when conducting. For each of the switching circuit units (SU₁, SU₂) and a respective one of the third memory units (MU3₁, MU3₂), the third LBL (LBL3) of each of the switching circuits (SC₁-SC_{16KB}) is coupled to the 3D NAND strings (NS) of a respective one of the memory groups (MG₁-MG_{16KB}). For each of the switching circuit units (SU₁, SU₂) and a respective one of the fourth memory units (MU4₁, MU4₂) the fourth LBL (LBL4) of each of the switching circuits (SC₁-SC_{16KB}) is coupled to the 3D NAND strings (NS) of a respective one of the memory groups (MG₁-MG_{16KB}).

Each of a first quarter of the LBL switch control lines (LG₁, LG₅) is coupled to the first LBL switches (LS1) of the switching circuits (SC₁-SC_{16KB}) of respective one of the switching circuit units (SU₁, SU₂), and is used to transmit a respective control signal for controlling operation of the first LBL switches (LS1) coupled thereto between conduction and non-conduction; each of a second quarter of the LBL switch control lines (LG₂, LG₆) is coupled to the second LBL switches (LS2) of the switching circuits (SC₁-SC_{16KB})of a respective one of the switching circuit units (SU₁, SU₂), and is used to transmit a respective control signal for controlling operation of the second LBL switches (LS2) coupled thereto between conduction and non-conduction; each of a third quarter of the LBL switch control lines (LG₃, LG₇) is coupled to the third LBL switches (LS3) of the switching circuits (SC₁-SC_{16KB}) of a respective one of the switching circuit units (SU₁, SU₂), and is used to transmit a respective control signal for controlling operation of the third LBL switches (LS3) coupled thereto between conduction and non-conduction; and each of a fourth quarter of the LBL switch control lines (LG₄, LG₈) is coupled to the fourth LBL switches (LS4) of the switching circuits (SC₁-SC_{16KB}) of a respective one of the switching circuit units (SU₁, SU₂), and is used to transmit a respective control signal for controlling operation of the fourth LBL switches (LS4) coupled thereto between conduction and non-conduction.

Each of a first half of the tie switch control lines TIE₁, TIE₃) is coupled to the first tie switches (TS1) of the switching circuits (SC₁-SC_{16KB}) of a respective one of the switching circuit units (SU₁, SU₂), and is used to transmit a respective control signal for controlling operation of the first tie switches (TS1) coupled thereto between conduction and non-conduction. Similarly, each of a second half of the tie switch control lines (TIE₂, TIE₄) is coupled to the second tie switches (TS2) of the switching circuits (SC₁-SC_{16KB}) of a respective one of the switching circuit units (SU₁-SU₂), and is used to transmit a respective control signal for controlling operation of the second tie switches (TS2) coupled thereto between conduction and non-conduction.

Each of the common source lines (CSL₁-CSL₄) is coupled to the 3D NAND strings (NS) of a respective one of the first and third memory units (MU1₁, MU1₂, MU3₁, MU3₂), the 3D NAND strings (NS) of a respective one of the second and fourth memory units (MU2₁, MU2₂, MU4₁, MU4₂) and the 3D capacitor strings (CS) of a respective one of the first and second DCR units (DCRU1₁, DCRU1₂, DCRU2₁, DCRU2₂).

It should be noted that, in this embodiment, the 3D NAND strings (NS) of the third and fourth memory units (MU3₁, MU3₂, MU4₁, MU4₂) are coplanar with the 3D NAND strings (NS) of the first and second memory units (MU1₁, MU1₂, MU2₁, MU2₂) and the 3D capacitor strings (CS) of the first and second DCR units (DCRU1₁, DCRU1₂, DCRU2₁, DCRU2₂); the switches (LS3, LS4, TS2) of the switching circuit units (SU₁, SU₂) are coplanar with the switches (LS1, LS2, DCRS1, DCRS2, TS1) of the switching circuit units (SU₁, SU₂), the data registers (DR₁-DR_{16KB}) of the data register units (DRU₁, DRU₂) and the DL switches (DS₁-DS_{16KB}) of the DL switch units (DSU₁, DSU₂); and each of the switches (LS3, LS4, TS2) may be a transistor with a 2D or 3D structure.

For each of the first to fourth memory units (MU1₁, MU1₂, MU2₁, MU2₂, MU3₁, MU3₂, MU4₁, MU4₂), since the corresponding LBL switches (LS1/LS2/LS3/LS4) of the switching circuits (SC₁-SC_{16KB}) of the corresponding one of the switching circuit units (SU₁, SU₂) are controlled by the same control signal, and since the DL switches (DS₁-DS_{16KB}) of the corresponding one of the DL switch units (DSU₁, DSU₂) are controlled by the same control signal, all bit line operations (e.g., all bit line program, all bit line read, etc.) can be achieved. In addition, for each of the first and second DCR units (DCRU1₁, DCRU1₂, DCRU2₁, DCRU2₂), since the corresponding DCR switches (DCRS1/DCRS2) of the first and second halves of the switching circuits (SC₁-SC_{16KB}) of the corresponding one of the switching circuit units (SU₁, SU₂) are controlled by different control signals, half bit line operations (e.g., half bit line recall, etc.) can be achieved.

The hierarchical NAND memory device of this embodiment is capable of performing concurrent and pipeline operations (e.g., program, read, erase, etc.). In an example of the concurrent operations, a number (J) of pages of data (with each page including a number (N) (i.e., 16 KB in this embodiment) of bits) are transferred sequentially from the DL unit (DU) and respectively to a number (J) of the first DCR units (DCRU₁, DCRU1₂) page by page, and then are concurrently and respectively programmed into a number (J) of the first memory units (MU1₁, MU1₂), where J is an integer and 2≤J≤M (i.e., J=2 in this embodiment). In another example of the concurrent operations, a number (J) of pages of data (with each page including a number (N) (i.e., 16 KB in this embodiment) of bits) respectively stored in a number (J) of the third memory units (MU3₁, MU3₂) are concurrently and respectively read to (the third LBLs (LBL3) of) a number (J) of the switching circuit units (SU₁, SU₂), and then are sequentially transferred to the DL unit (DU) page by page. The pipeline operations of the hierarchical NAND memory device of this embodiment are similar to those of the conventional NAND memory device, and details thereof are omitted herein for the sake of brevity.

It should be noted that, when a total number of the first to fourth memory units MU1₁, MU1₂, MU2₁, MU2₂, MU3₁, MU3₂, MU4₁, MU4₂) of the third embodiment is equal to the number of the first memory units (MU1₁-MU1₈) (see FIGS. 1 and 2) of the first embodiment, a number of the data register units (DRU₁, DRU₂) required in this embodiment is a quarter of the number of the data register units (DRU₁-DRU₈) (see FIGS. 1 and 2) required in the first embodiment, which is beneficial to reduce the size of the hierarchical NAND memory device of this embodiment.

In view of the above, the hierarchical NAND memory device of this embodiment has the following advantages:

1. Since the first LBL (LBL1) of each of the switching circuits (SC₁-SC_{16KB}) of the switching circuit units (SU₁, SU₂) is coupled to the 3D NAND strings (NS) of a respective one of the memory groups (MG₁-MG_{16KB}) of the first memory units (MU1₁, MU1₂), since the second LBL (LBL2) of each of the switching circuits (SC₁-SC_{16KB}) of the switching circuit units (SU₁, SU₂) is coupled to the 3D NAND strings (NS) of a respective one of the memory groups (MG₁-MG_{16KB}) of the second memory units (MU2₁, MU2₂), since the third LBL (LBL3) of each of the switching circuits (SC₁-SC_{16KB}) of the switching circuit units (SU₁, SU₂) is coupled to the 3D NAND strings (NS) of a respective one of the memory groups (MG₁-MG_{16KB}) of the third memory units (MU3₁, MU3₂), and since the fourth LBL (LBL4) of each of the switching circuits (SC₁-SC_{16KB}) of the switching circuit units (SU₁, SU₂) is coupled to the 3D NAND strings (NS) of a respective one of the memory groups (MG₁-MG_{16KB}) of the fourth memory units (MU4₁, MU4₂), each of the first to fourth LBLs (LBL1-LBL4) can have a relatively small capacitance, resulting in relatively short latency and relatively low power consumption of the hierarchical NAND memory device.

2. Since the hierarchical NAND memory device can perform concurrent operations, each of the 3D NAND strings (NS) of the memory groups (MG₁-MG_{16KB}) of the first to fourth memory units (MU₁, MU1₂, MU2₁, MU2₂, MU3₁, MU3₂, MU4₁, MU4₂) would not have to frequently withstand high-voltage (e.g. 20V) or medium-high-voltage (e.g., 6V or 10V) stresses, resulting in relatively good data reliability of the hierarchical NAND memory device.

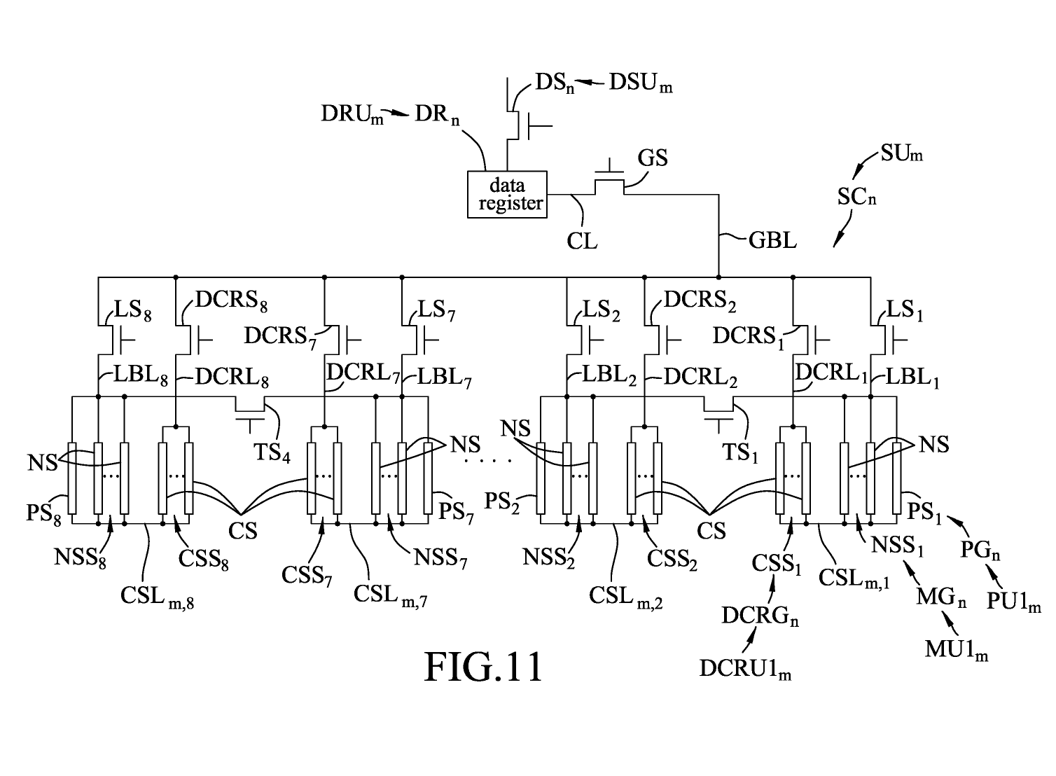

Referring to FIG. 11, a fourth embodiment of the hierarchical NAND memory device according to the disclosure is a modification of the first embodiment, and differs from the first embodiment in that: (a) the hierarchical NAND memory device further includes a number (M) (i.e., eight in this embodiment) of pre-charge units (PU₁-PU₈); (b) the 3D NAND strings (NS) of each of the memory groups (MG₁-MG_{16KB}) are divided into a number (P) of 3D NAND string sets (NSS₁-NSS_{P}) (where P is an even integer greater than or equal to two); (c) the 3D capacitor strings (CS) of each of the DCR groups (DCRG₁-DCRG_{16KB}) are divided into a number (P) of 3D capacitor string sets (CSS₁-CSS_{P}); and (d) the hierarchical NAND memory device includes a number (M×P) (i.e., sixty-four in this embodiment) of common source lines (CSL_{1,1} -CSL_{1,8}, CSL_{2,1}-CSL_{2,8}, . . . , CSL_{8,1}-CSL_{8,8}), instead of a number (M) of common source lines. In addition, the fourth embodiment further differs from the first embodiment in the configuration of each of the switching circuits (SC₁-SC_{16KB}). For illustration purposes, P=8 in this embodiment.

In the fourth embodiment, the pre-charge units (PU₁-PU₈) are arranged in the first direction (X) (see FIG. 1). Each of the pre-charge units (PU₁-PU₈) includes a number (N) (i.e., 16 KB in this embodiment) of pre-charge groups (PG₁-PG_{16KB}) which are arranged in the second direction (Y) (see FIG. 1), and each of which includes a number (P) (i.e., eight in this embodiment) of 3D pre-charge strings (PS₁-PS₈). Each of the 3D pre-charge strings (PS₁-PS₈) extends in the third direction (Z) (see FIG. 4).

Each of the switching circuits (SC₁-SC_{16KB}) includes a number (P) (i.e., eight in this embodiment) of LBLs (LBL₁-LBL₈), a number (P) of DCRLs (DCRL₁-DCRL₈), a global bit line (GEL) (GBL), a connecting line (CL), a number (P) of LBL switches (LS₁-LS₈) each coupled between a respective one of the LBLs (LBL₁-LBL₈) and the GBL (GBL) of the switching circuit, a number (P) of DCR switches (DCRS₁-DCRS₈) each coupled between a respective one of the DCRLs (DCRL₁-DCRL₈) and the GBL (GBL) of the switching circuit, a GBL switch (GS) coupled between the GBL (GBL) and the connecting line (CL) of the switching circuit, and a number (P/2) of tie switches (TS₁-TS₄) each coupled between corresponding two of the LBLs (LBL₁-LBL₈) of the switching circuit. For each of the switching circuits (SC₁-SC_{16KB}) of the switching circuit units (SU₁-SU₈), the respective one of the memory groups (MG₁-MG_{16KB}) of the first memory units (MU1₁-MU1₈) and a respective one of the pre-charge groups (PG₁-PG_{16KB}) of the pre-charge units (PU₁-PU₈), each of the LBLs (LBL₁-LBL₈) is coupled to the 3D NAND strings (NS) of a respective one of the 3D NAND string sets (NSS₁-NSS₈), and is coupled further to a respective one of the 3D pre-charge strings (PS₁-PS₈) for being pre-charged thereby. For each of the switching circuits (SC₁-SC_{16KB}) of the switching circuit units (SU₁-SU₈) and the respective one of the DCR groups (DCRG₁-DCRG1_{16KB}) of the first DCR units (DCRU1₁-DCRU1₈), each of the DCRLs (DCRL₁-DCRL₈) is coupled to the 3D capacitor strings (CS) of a respective one of the 3D capacitor string sets (CSS₁-CSS₈). For each of the data register units (DRU₁-DRU₈) and the respective one of the switching circuit units (SU₁-SU₈), each of the data registers (DR₁-DR_{16KB}) is coupled to the connecting line (CL) of the respective one of the switching circuits (SC₁-SC_{16KB}).

For an m^{th} group of the common source lines (CSL_{m,1}-CSL_{m,8}) and a respective one of the switching circuit units (SUₘ), a p^{th} one of the common source lines (CSL_{m,p}) is coupled to the 3D NAND strings (NS), the 3D capacitor strings (CS) and the 3D pre-charge strings (PSₚ) that are coupled to the LBLs (LBLₚ) and the DCRLs (DCRLₚ) of the switching circuits (SC₁-SC_{16KB}), where 1≤m≤8 and 1≤p≤8.

It should be noted that, in this embodiment, the pre-charge strings (PS) of the pre-charge units (PU₁-PU₈) are coplanar with the 3D NAND strings (NS) of the first memory units (MU1₁-MU1₈) and the 3D capacitor strings (CS) of the first DCR units (DCRU1₁-DCRU1₈); the switches (LS₁-LS₈, DCRS₁-DCRS₈, GS, TS₁-TS₄) of the switching circuit units (SU₁-SU₈) are coplanar with the data register units (DR₁-DR_{16KB}) of the data register units (DRU₁-DRU₈) and the DL switches (DS₁-DS_{16KB}) of the DL switch units (DSU₁-DSU₈); and each of the switches (LS₁-LS₈, DCRS₁-DCRS₈, GS, TS₁-TS₄) may be a transistor with a 2D or 3D structure. Moreover, in an example, for each of the switching circuits (SC₁-SC_{16KB}), a ratio of a parasitic capacitance of each of the LBLs (LBL₁-LBL₈) to a parasitic capacitance of the GBL (GBL) is designed to be about ten, but the disclosure is not limited thereto. In addition, the common source lines (CSL_{m,1}-CSL_{m,8}), the LBLs (LBL₁-LBL₈) and the GBLs (GBL) may be formed on the same surface (e.g., the first surface 21 (see FIG. 5)) of the substrate 2 (see FIG. 5), with the common source lines (CSL_{m,1}-CSL_{m,8}) in a first layer, the LBLs (LBL₁-LBL₈) in a second layer and the GBLs (GBL) in a third layer. For example, among the first to third layers, one of the first and third layers may be nearest to the first surface 21 (see FIG. 5), the other one of the first and third layers may be farthest to the first surface 21 (see FIG. 5), and the second layer may be in the middle of the first and third layers.

In view of the above, the hierarchical NAND memory device of this embodiment has the following advantages:

1. Since each of the LBLs (LBL₁-LBL₈) of the switching circuits (SC₁-SC_{16KB}) of the switching circuit units (SU₁-SU₈) is coupled to the 3D NAND strings (NS) of a respective one of the 3D NAND string sets (NSS₁-NSS₈) of the memory groups (MG₁-MG_{16KB}) of the first memory units (MU1₁-MU1₈), each of the LBLs (LBL₁-LBL₈) can have a relatively small capacitance, resulting in relatively short latency and relatively low power consumption of the hierarchical NAND memory device.

2. The hierarchical NAND memory device can perform concurrent operations, and therefore each of the 3D NAND strings (NS) of the memory groups (MG₁-MG_{16KB}) of the first memory units (MU1₁-MU1₈) would not have to frequently withstand high-voltage (e.g. 20V) or medium-high-voltage (e.g., 6V or 10V) stresses, resulting in relatively good data reliability of the hierarchical NAND memory device.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that the disclosure is not limited to the disclosed embodiments but is intended to cover various arrangements included within the spirit and scope of the broadest interpretation so as to encompass all such modifications and equivalent arrangements.

What is claimed is:

1. A hierarchical NAND memory device comprising:
a number (M) of first memory units arranged in a first direction, each of said first memory units including a number (N) of memory groups which are arranged in a second direction orthogonal to the first direction, and each of which includes a plurality of three-dimensional (3D) NAND strings, where each of M and N is an integer greater than or equal to two;
a number (M) of first dynamic cache register (DCR) units arranged in the first direction, each of said first DCR units including a number (N) of DCR groups which are arranged in the second direction, and each of which includes a plurality of 3D capacitor strings;
a number (M) of switching circuit units each including a number (N) of switching circuits;
for each of said switching circuit units, a respective one of said first memory units and a respective one of said first DCR units, each of said switching circuits being coupled to said 3D NAND strings of a respective one of said memory groups and said 3D capacitor strings of a respective one of said DCR groups;
a number (M) of data register units each including a number (N) of data registers;
for each of said data register units and a respective one of said switching circuit units, each of said data registers being coupled to a respective one of said switching circuits;
a data line (DL) unit including a number (N) of DLs; and
a number (M) of DL switch units each including a number (N) of DL switches;
for each of said DL switch units, a respective one of said data register units and said DL unit, each of said DL switches being coupled between a respective one of said data registers and a respective one of said DLs.

2. The hierarchical NAND memory device of claim 1, wherein:
each of said switching circuits includes a first local bit line (LBL), a first DCR line, a connecting line, a first LBL switch that is coupled between said first LBL and said connecting line of said switching circuit, and a first DCR switch that is coupled between said first DCR line and said connecting line of said switching circuit;
for each of said switching circuit units and said respective one of said first memory units, said first LBL of each of said switching circuits is coupled to said 3D NAND strings of said respective one of said memory groups;
for each of said switching circuit units and said respective one of said first DCR units, said first DCR line of each of said switching circuits is coupled to said 3D capacitor strings of said respective one of said DCR groups;
for each of said data register units and said respective one of said switching circuit units, each of said data registers is coupled to said connecting line of said respective one of said switching circuits.

3. The hierarchical NAND memory device of claim 2, further comprising:
a number (M) of LBL switch control lines, each of which is coupled to said first LBL switches of said switching circuits of a respective one of said switching circuit units, and each of which is used to transmit a respective control signal for controlling operation of said first LBL switches coupled thereto between conduction and non-conduction;
a number (M) of DL switch control lines, each of which is coupled to said DL switches of a respective one of said DL switch units, and each of which is used to transmit a respective control signal for controlling operation of said DL switches coupled thereto between conduction and non-conduction;
a number (M) of first DCR switch control lines, each of which is coupled to said first DCR switches of a first half of said switching circuits of a respective one of said switching circuit units, and each of which is used to transmit a respective control signal for controlling operation of said first DCR switches coupled thereto between conduction and non-conduction; and
a number (M) of second DCR switch control lines, each of which is coupled to said first DCR switches of a second half of said switching circuits of a respective one of said switching circuit units, and each of which is used to transmit a respective control signal for controlling operation of said first DCR switches coupled thereto between conduction and non-conduction.

4. The hierarchical NAND memory device of claim 3, wherein, for each of said first DCR units and said respective one of said switching circuit units, some of said DCR groups that respectively correspond to said first DCR switches of said first half of said switching circuits are interleaved in the second direction with some of said DCR groups that respectively correspond to said first DCR switches of said second half of said switching circuits.

5. The hierarchical NAND memory device of claim 2, further comprising:
a number (M) of second memory units arranged in the first direction, each of said second memory units including a number (N) of memory groups which are arranged in the second direction, and each of which includes a plurality of 3D NAND strings; and
a number (M) of second DCR units arranged in the first direction, each of said second DCR units including a number (N) of DCR groups which are arranged in the second direction, and each of which includes a plurality of 3D capacitor strings;
wherein each of said switching circuits further includes a second LBL, a second DCR line, a second LBL switch that is coupled between said second LBL and said connecting line of said switching circuit, and a second DCR switch that is coupled between said second DCR line and said connecting line of said switching circuit;
wherein, for each of said switching circuit units and a respective one of said second memory units, said second LBL of each of said switching circuits is coupled to said 3D NAND strings of a respective one of said memory groups;
wherein, for each of said switching circuit units and a respective one of said second DCR units, said second DCR line of each of said switching circuits is coupled to said 3D capacitor strings of a respective one of said DCR groups.

6. The hierarchical NAND memory device of claim 5, wherein each of said switching circuits further includes a tie switch that is coupled between said first and second LBLs of said switching circuit.

7. The hierarchical NAND memory device of claim 5, further comprising:
a number (2×M) of LBL switch control lines, each of a first half of said LBL switch control lines being coupled to said first LBL switches of said switching circuits of a respective one of said switching circuit units, and being used to transmit a respective control signal for controlling operation of said first LBL switches coupled thereto between conduction and non-conduction, each of a second half of said LBL switch control lines being coupled to said second LBL switches of said switching circuits of a respective one of said switching circuit units, and being used to transmit a respective control signal for controlling operation of said second LBL switches coupled thereto between conduction and non-conduction;
a number (M) of DL switch control lines, each of which is coupled to said DL switches of a respective one of said DL switch units, and each of which is used to transmit a respective control signal for controlling operation of said DL switches coupled thereto between conduction and non-conduction;
a number (2×M) of first DCR switch control lines, each of a first half of said first DCR switch control lines being coupled to said first DCR switches of a first half of said switching circuits of a respective one of said switching circuit units, and being used to transmit a respective control signal for controlling operation of said first DCR switches coupled thereto between conduction and non-conduction, each of a second half of said first DCR switch control lines being coupled to said second DCR switches of said first half of said switching circuits of a respective one of said switching circuit units, and being used to transmit a respective control signal for controlling operation of said second DCR switches coupled thereto between conduction and non-conduction; and
a number (2×M) of second DCR switch control lines, each of a first half of said second DCR switch control lines being coupled to said first DCR switches of a second half of said switching circuits of a respective one of said switching circuit units, and being used to transmit a respective control signal for controlling operation of said first DCR switches coupled thereto between conduction and non-conduction, each of a second half of said second DCR switch control lines being coupled to said second DCR switches of said second half of said switching circuits of a respective one of said switching circuit units, and being used to transmit a respective control signal for controlling operation of said second DCR switches coupled thereto between conduction and non-conduction.

8. The hierarchical NAND memory device of claim 7, wherein:
for each of said first DCR units and said respective one of said switching circuit units, some of said DCR groups that respectively correspond to said first DCR switches of said first half of said switching circuits are interleaved in the second direction with some of said DCR groups that respectively correspond to said first DCR switches of said second half of said switching circuits;
for each of said second DCR units and said respective one of said switching circuit units, some of said DCR groups that respectively correspond to said second DCR switches of said first half of said switching circuits are interleaved in the second direction with some of said DCR groups that respectively correspond to said second DCR switches of said second half of said switching circuits.

9. The hierarchical NAND memory device of claim 5, further comprising:
a number (M) of third memory units arranged in the first direction; and
a number (M) of fourth memory units arranged in the first direction;
each of said third and fourth memory units including a number (N) of memory groups which are arranged in the second direction, and each of which includes a plurality of 3D NAND strings;
wherein each of said switching circuits further includes a third LBL, a fourth LBL, a third LBL switch that is coupled between said third LBL and said connecting line of said switching circuit, and a fourth LBL switch that is coupled between said fourth LBL and said connecting line of said switching circuit;
wherein, for each of said switching circuit units and a respective one of said third memory units, said third LBL of each of said switching circuits is coupled to said 3D NAND strings of a respective one of said memory groups;
wherein, for each of said switching circuit units and a respective one of said fourth memory units, said fourth LBL of each of said switching circuits is coupled to said 3D NAND strings of a respective one of said memory groups.

10. The hierarchical NAND memory device of claim 9, wherein each of said Switching circuits further includes a first tie switch that is coupled between said first and second LBLs of said switching circuit, and a second tie switch that is coupled between said third and fourth LBLs of said switching circuit.

11. The hierarchical NAND memory device of claim 9, further comprising:
a number (4×M) of LBL switch control lines, each of a first quarter of said LBL switch control lines being coupled to said first LBL switches of said switching circuits of a respective one of said switching circuit units, and being used to transmit a respective control signal for controlling operation of said first LBL switches coupled thereto between conduction and non-conduction, each of a second quarter of said LBL switch control lines being coupled to said second LBL switches of said switching circuits of a respective one of said switching circuit units, and being used to transmit a respective control signal for controlling operation of said second LBL switches coupled thereto between conduction and non-conduction, each of a third quarter of said LBL switch control lines being coupled to said third LBL switches of said switching circuits of a respective one of said switching circuit units, and being used to transmit a respective control signal for controlling operation of said third LBL switches coupled thereto between conduction and non-conduction, each of a fourth quarter of said LBL switch control lines being coupled to said fourth LBL switches of said switching circuits of a respective one of said switching circuit units, and being used to transmit a respective control signal for controlling operation of said fourth LBL switches coupled thereto between conduction and non-conduction;
a number (M) of DL switch control lines, each of which is coupled to said DL switches of a respective one of said DL switch units, and each of which is used to transmit a respective control signal for controlling operation of said DL switches coupled thereto between conduction and non-conduction;
a number (2×M) of first DCR switch control lines, each of a first half of said first DCR switch control lines being coupled to said first DCR switches of a first half of said switching circuits of a respective one of said switching circuit units, and being used to transmit a respective control signal for controlling operation of said first DCR switches coupled thereto between conduction and non-conduction, each of a second half of said first DCR switch control lines being coupled to said second DCR switches of said first half of said switching circuits of a respective one of said switching circuit units, and being used to transmit a respective control signal for controlling operation of said second DCR switches coupled thereto between conduction and non-conduction; and
a number (2×M) of second DCR switch control lines, each of a first half of said second DCR switch control lines being coupled to said first DCR switches of a second half of said switching circuits of a respective one of said switching circuit units, and being used to transmit a respective control signal for controlling operation of said first DCR switches coupled thereto between conduction and non-conduction, each of a second half of said second DCR switch control lines being coupled to said second DCR switches of said second half of said switching circuits of a respective one of said switching circuit units, and being used to transmit a respective control signal for controlling operation of said second DCR switches coupled thereto between conduction and non-conduction.

12. The hierarchical NAND memory device of claim 11, wherein:
for each of said first DCR, units and said respective one of said switching circuit units, some of said DCR groups that respectively correspond to said first DCR, switches of said first half of said switching circuits are interleaved in the second direction with some of said DCR groups that respectively correspond to said first DCR switches of said second half of said switching circuits;
for each of said second DCR units and said respective one of said switching circuit units, some of said DCR groups that respectively correspond to said second DCR switches of said first half of said switching circuits are interleaved in the second direction with some of said DCR groups that respectively correspond to said second DCR switches of said second half of said switching circuits.

13. The hierarchical NAND memory device of claim 1, wherein:
each of said switching circuits includes a plurality of switches;
said 3D NAND strings, said 3D capacitor strings, said switches of said switching circuits, said data registers and said DL switches are formed on a first surface of a substrate, with said 3D NAND strings and said 3D capacitor strings in a layer and said switches of said switching circuits, said data registers and said DL switches in another layer.

14. The hierarchical NAND memory device of claim 13, wherein said 3D NAND strings and said 3D capacitor strings overlap with said switches of said switching circuits, said data registers and said DL switches.

15. The hierarchical NAND memory device of claim 1, further comprising a number (M) of pre-charge units arranged in the first direction, wherein:
each of said pre-charge units includes a number (N) of pre-charge groups which are arranged in the second direction, and each of which includes a number (P) of 3D pre-charge strings, where P is an even integer greater than or equal to two;
said 3D NAND strings of each of said memory groups are divided into a number (P) of 3D NAND string sets;
said 3D capacitor strings of each of said DCR groups are divided into a number (P) of 3D capacitor string sets;
each of said switching circuits includes a number (P) of LBLs, a number (P) of DCRLs, a global bit line (GBL), a connecting line, a number (P) of LBL switches each coupled between a respective one of said LBLs and said GBL of said switching circuit, a number (P) of DCR switches each coupled between a respective one of said DCRLs and said GBL of said switching circuit, a GBL switch coupled between said GEL and said connecting line of said switching circuit, and a number (P/2) of tie switches each coupled between corresponding two of said LBLs of said switching circuit;
for each of said switching circuits of said switching circuit units, said respective one of said memory groups of said first memory units and a respective one of said pre-charge groups of said pre-charge units, each of said LBLs is coupled to said 3D NAND strings of a respective one of said 3D NAND string sets and a respective one of said 3D pre-charge strings;
for each of said switching circuits of said switching circuit units and said respective one of said DCR groups of said first DCR units, each of said DCRLs is coupled to said 3D capacitor strings of a respective one of said 3D capacitor string sets;
for each of said data register units and said respective one of said switching circuit units, each of said data registers is coupled to said connecting line of said respective one of said switching circuits.
